(19) United States
(12) Patent Application Publication
(10) Pub. No.: US 2020/0203618 A1
(43) Pub. Date: Jun. 25, 2020

(54) ORGANIC LIGHT-EMITTING DISPLAY DEVICE AND DISPLAY APPARATUS

(71) Applicants: Kunshan New Flat Panel Disp. Tech. Center Co., Ltd, Kunshan (CN); Kunshan Go-Visionox Opto-Electronics Co., Ltd., Kunshan (CN)

(72) Inventors: Li Weiwei, Kunshan (CN); Song Liu, Kunshan (CN); Jing Xie, Kunshan (CN); Chao Min, Kunshan (CN); Fei Zhao, Kunshan (CN); Song Gao, Kunshan (CN)

(73) Assignees: Kunshan New Flat Panel Disp. Tech. Center Co., Ltd, Kunshan (CN); Kunshan Go-Visionox Opto-Electronics Co., Ltd., Kunshan (CN)

(21) Appl. No.: 15/781,446

(22) PCT Filed: Dec. 2, 2016
(86) PCT No.: PCT/CN2016/108389

§ 371 Date: Jun. 4, 2018

(30) Foreign Application Priority Data
Dec. 15, 2015 (CN) 201510937461.6

(51) Int. Cl. H01L 51/00; C09K 11/06

(52) U.S. Cl. CPC H01L 51/0061; H01L 51/0072; H01L 51/5004; C09K 11/06; H01L 51/0067

(57) ABSTRACT

An organic light-emitting display device (100). A functional structure layer (130) of the organic light-emitting display device (100) comprises a hole injection layer (131), a first hole transport layer (1321), a second hole transport layer (1322), an organic light-emitting layer (133), an electron transport layer (134) and an electron injection layer (135) which are sequentially laminated on a first electrode (110). The highest occupied orbital energy level of the material of the first hole transport layer (1321) is less than the highest occupied orbital energy level of the second hole transport layer (1322). A triplet state energy level of the material of the second hole transport layer (1322) is greater than 2.5 eV. The organic light-emitting layer (133) comprises a main light-emitting material, and the main light-emitting material comprises a thermal activation delay fluorescent material. The organic light-emitting display device (100) adopts two hole transport layers, wherein the second hole transport layer (1322) acts as both an electron blocking layer and an optical compensation layer, and matches the thermal activation delay fluorescent material in the organic light-emitting layer (133), thereby improving the current efficiency and service life of the organic light-emitting display device (100).

### FIELD

The present disclosure relates to the field of flat panel display technology, especially to an organic light-emitting display and a display device.

### BACKGROUND

At present, an organic light-emitting display (OLED) is divided into a single host OLED and a dual host OLED, wherein the single host OLED has the problem of low current efficiency and short service life, while the dual host OLED is more beneficial to the carrier balance adjustment and has better performance compared with the single host OLED. However, the dual host OLED requires high process stability. A slight ratio variation of two host materials of the dual host OLED would cause great change of OLED performance, which is a big challenge to product yield on production line.

### SUMMARY

Based on the above, to resolve the problem of low current efficiency and short service life of the conventional single host OLED, an organic light-emitting display with high current efficiency and long service life is provided.

An organic light-emitting display includes:

a first electrode;

a second electrode; and

a functional structure layer located between the first electrode and the second electrode, wherein the functional structure layer includes a hole injection layer, a first hole transport layer, a second hole transport layer, an organic light-emitting layer, an electron transport layer, and an electron injection layer which are sequentially laminated on the first electrode,

wherein a highest occupied orbital energy level of a first material forming the first hole transport layer is less than a highest occupied orbital energy level of a second material forming the second hole transport layer; a triplet state energy level of the second material is greater than 2.5 eV;

the organic light-emitting layer includes a light-emitting material, the light-emitting material includes a thermal activation delay fluorescent material.

In one embodiment, the second material forming the second hole transport layer is selected from a compound represented by a structural formula (1) below

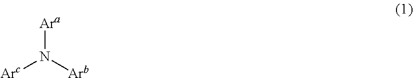

wherein

—Ar^{a} is represented by a structural formula (1-1) or (1-2) below,

-L^{a}Ar^{d})ₙ (1-1)

-L^{a}-CH₃₋ₙ∛Ar^{d})ₙ (1-2)

where -L^{a} is selected from aromatic ring containing 6 to 25 ring carbon atoms, or aromatic heterocyclic ring containing 5 to 25 ring atoms, —Ar^{d} is selected from aryl group containing 6 to 25 ring carbon atoms, or heteroaryl group containing 5 to 25 ring atoms, n is selected from 2 or 3, and a plurality of —Ar^{d} are same or different;

—Ar^{b} is represented by a structural formula (1-3) below

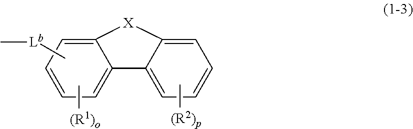

where -L^{b} is selected from an arylene group containing 6 to 25 ring carbon atoms, or heteroarylene group containing 5 to 25 ring atoms; L^{b} is connected to a ring connecting with R¹ by a single bond,

R¹ and R² are each independently selected from alkyl group containing 1 to 15 carbon atoms, alkenyl group containing 2 to 15 carbon atoms, naphthenic group containing 3 to 15 ring carbon atoms, aryl group containing 6 to 25 ring carbon atoms, heteroaryl group containing 5 to 25 ring atoms, trialkylsilyl group formed by alkyl groups each containing 1 to 15 carbon atoms, triarylsilyl group formed by aryl groups each containing 6 to 25 ring carbon atoms, alkylarylsilyl group formed by alkyl group containing 1 to 15 carbon atoms and aryl group containing 6 to 25 ring carbon atoms, carbazolyl group, halogen atom, or cyano group, o is selected from an integer of 0 to 3, p is selected from an integer of 0 to 4, a plurality of R¹ adjacent to each other are bondable to each other to form a ring, a plurality of R² adjacent to each other are bondable to each other to form a ring, R¹ and R² are bondable to each other to form a ring, X is selected from CR³R⁴, NR⁵, O or S, and R³, R⁴, and R⁵ each are independently selected from an alkyl group containing 1 to 15 carbon atoms, or aryl group containing 6 to 25 ring carbon atoms; and

Ar^{c} is selected from aryl group containing 6 to 50 ring carbon atoms or heteroaryl group containing 5 to 25 ring atoms, or a structure represented by the structural formula (1-1), (1-2), or (1-3).

In one embodiment, a thickness of the second hole transport layer is 20-50 nm.

In one embodiment, a thickness of the second hole transport layer is 35-45 nm.

In one embodiment, the light emitting host material include a green light thermal activation delay fluorescent material.

In one embodiment, the light emitting host material is selected from a compound represented by a structural formula (2) below

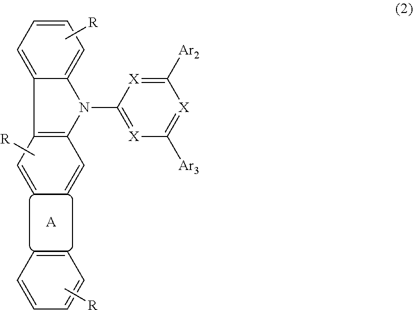

wherein

a ring A is represented by a structural formula (2-1) below

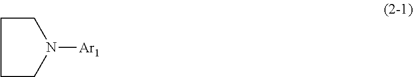

the ring A and a ring adjacent to the ring A form a condensed ring; X is selected from N or CH, and at least one X is selected from N; Ar₁, Ar₂, and Ar₃ are each independently selected from non-condensed ring aryl hydrocarbon substituent, or non-condensed ring aryl heterocyclic substituent, and it is not ruled out that Ar₂ and Ar₃ form a condensed ring structure through an aromatic ring containing heteroatom; and R is selected from H atom or monovalent substituent.

In one embodiment, the light emitting host material is selected from one of compounds represented by the following structure structural formulas:

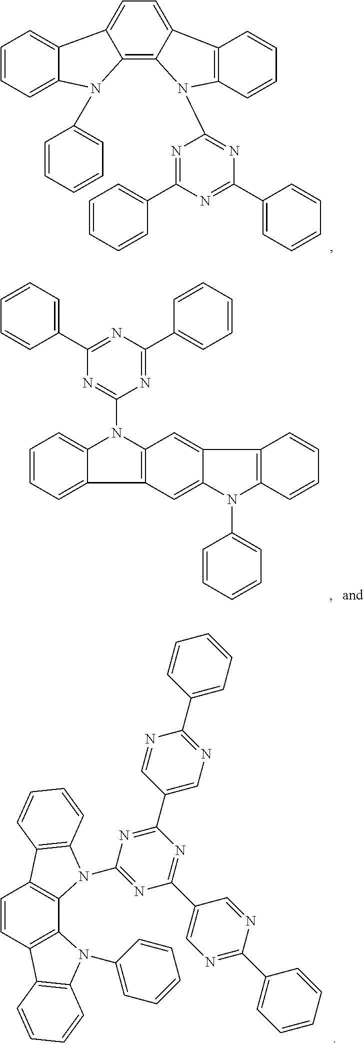

In one embodiment, the light emitting host material comprises a red light thermal activation delay fluorescent material.

In one embodiment, a thickness of the first hole transport layer is 1-40 nm.

A display device including the above organic light-emitting display is further provided in the present disclosure.

Compared with the prior art, the organic light-emitting display in the present disclosure adopts two hole transport layers, wherein the second hole transport layer acts as an electron blocking layer and an optical compensation layer, and is cooperated with the thermal activation delay fluorescent material of the organic light-emitting layer, thereby improving the current efficiency and service life of the organic light-emitting display.

### BRIEF DESCRIPTION OF THE DRAWINGS

FIG. 1 is a schematic diagram illustrating an organic light-emitting display according to one preferred embodiment of the present disclosure.

FIG. 2 is a schematic diagram illustrating an organic light-emitting display according to Comparative Example 1.

### DETAILED DESCRIPTION

In order to make the purpose, technical solutions and advantages of the present disclosure to be understood more clearly, the present disclosure will be described in further details with the accompanying drawings and the following embodiments. It should be understood that the specific embodiments described herein are merely examples to illustrate the present invention, not to limit the present disclosure.

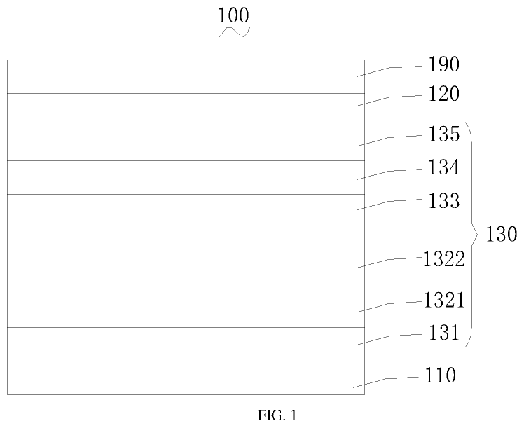

Referring to FIG. 1, an organic light-emitting display 100 may include a first electrode 110, a second electrode 120, and a functional structure layer 130 located between the first electrode 110 and the second electrode 120.

In this embodiment, the first electrode 110 may be an indium tin oxide electrode, and the second electrode 120 may be a silver electrode. Certainly, the first electrode 110 and the second electrode 120 are not limited to the above-mentioned electrodes, but can be other electrodes.

In this embodiment, the organic light-emitting display 100 may a top emitting organic light-emitting display. For optimal performance, a circular polarizer layer 190 is further disposed on one side of the second electrode 120 far away from the functional structure layer 130. Certainly, the circular polarizer layer 190 may not be disposed.

The functional structure layer 130 may include a hole injection layer 131, a first hole transport layer 1321, a second hole transport layer 1322, an organic light-emitting layer 133, an electron transport layer 134, and an electron injection layer 135 which are sequentially laminated on the first electrode 110.

Materials and thicknesses of the hole injection layer 131, the electron transport layer 134, and the electron injection layer 135 are well known to those skilled in the art and will not be repeated here.

In the present disclosure, the main function of the first hole transport layer 1321 is to transport holes. The second hole transport layer 1322 also serves as an electron blocking layer and an optical compensation layer apart from a hole transport layer.

A triplet state energy level of a material of the second hole transport layer 1322 may be greater than 2.5 eV. A highest occupied orbital energy level of the material of the second hole transport layer 1322 may be greater than a highest occupied orbital energy level of a material of the first hole transport layer 1321.

Preferably, the material of the first hole transport layer 1321 may be selected from NPB. Certainly, the material of the first hole transport layer 1321 is not limited to NPB and can be other hole transporting materials.

Preferably, a thickness of the first hole transport layer 1321 may be 1-40 nm, more preferably 5-20 nm.

Preferably, the material of the second hole transport layer 1322 may be aryl tertiary amine compound.

More preferably, the material of the second hole transport layer may be selected from a compound represented by structural formula (1) below

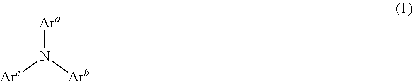

—Ar^{a} may be represented by a structural formula (1-1) or (1-2) below,

-L^{a}Ar^{d})ₙ (1-1)

-L^{a}-CH₃₋ₙAr^{d})ₙ (1-2)

where -L^{a} may be selected from aromatic ring containing 6 to 25 ring carbon atoms, or aromatic heterocyclic ring containing 5 to 25 ring atoms, —Ar^{d} may be selected from aryl group containing 6 to 25 ring carbon atoms, or heteroaryl group containing 5 to 25 ring atoms, n may be selected from 2 or 3, and a plurality of —Ar^{d} may be same or different.

—Ar^{b} may be represented by a structural formula (1-3) below

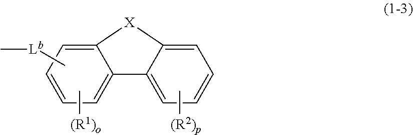

where -L^{b} may be selected from substituted or unsubstituted arylene containing 6 to 25 ring carbon atoms, or substituted or unsubstituted heteroarylene containing 5 to 25 ring atoms, and L^{b} may be connected to a ring connecting with R¹ by a single bond.

R¹ and R² may be each independently selected from an alkyl group containing 1 to 15 carbon atoms, alkenyl group containing 2 to 15 carbon atoms, naphthenic group containing 3 to 15 ring carbon atoms, aryl group containing 6 to 25 ring carbon atoms, heteroaryl group containing 5 to 25 ring atoms, trialkylsilyl group formed by alkyl groups each containing 1 to 15 carbon atoms, triarylsilyl group formed by aryl groups each containing 6 to 25 ring carbon atoms, alkylarylsilyl group formed by alkyl group containing 1 to 15 carbon atoms and aryl group containing 6 to 25 ring carbon atoms, carbazolyl group, halogen atom, or cyano group. o may be selected from an integer of 0 to 3. p may be selected from an integer of 0 to 4. A plurality of R¹ adjacent to each other may be bonded to each other to form a ring, a plurality of R² adjacent to each other may be bonded to each other to form a ring, and R¹ and R² may be bonded to each other to form a ring. X may be selected from CR³R⁴, NR⁵, O and S. R³, R⁴, and R⁵ may be each independently selected from substituted or unsubstituted alkyl group containing 1 to 15 carbon atoms, or substituted or unsubstituted aryl group containing 6 to 25 ring carbon atoms.

Ar^{c} may be selected from substituted or unsubstituted aryl group containing 6 to 50 ring carbon atoms or substituted or unsubstituted heteroaryl group containing 5 to 25 ring atoms, or a structure represented by the structural formula (1-1), (1-2), or (1-3).

The material of the second hole transport layer 1322 may be preferably selected from compounds represented by following structure structural formulas:

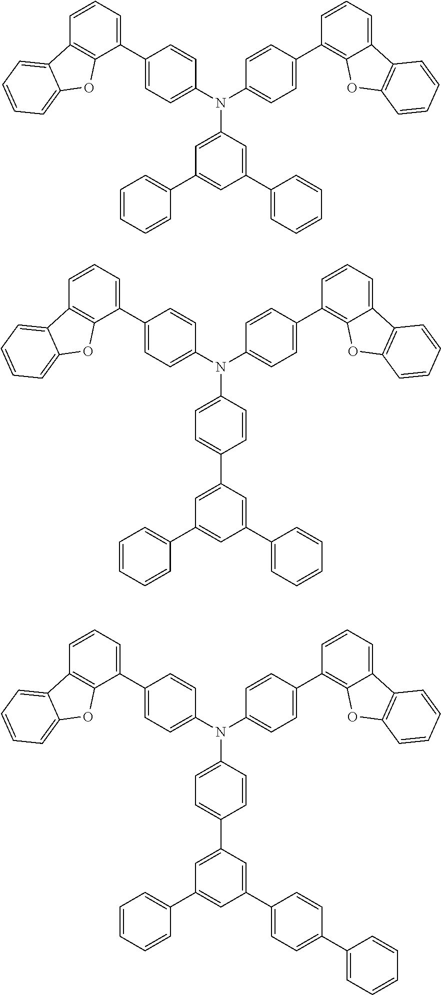 [SMILES: c1ccc(-c2cc(-c3ccccc3)cc(N(c3ccc(-c4cccc5c4oc4ccccc45)cc3)c3ccc(-c4cccc5c4oc4ccccc45)cc3)c2)cc1 ; c1ccc(-c2cc(-c3ccccc3)cc(-c3ccc(N(c4ccc(-c5cccc6c5oc5ccccc56)cc4)c4ccc(-c5cccc6c5oc5ccccc56)cc4)cc3)c2)cc1 ; c1ccc(-c2ccc(-c3cc(-c4ccccc4)cc(-c4ccc(N(c5ccc(-c6cccc7c6oc6ccccc67)cc5)c5ccc(-c6cccc7c6oc6ccccc67)cc5)cc4)c3)cc2)cc1]

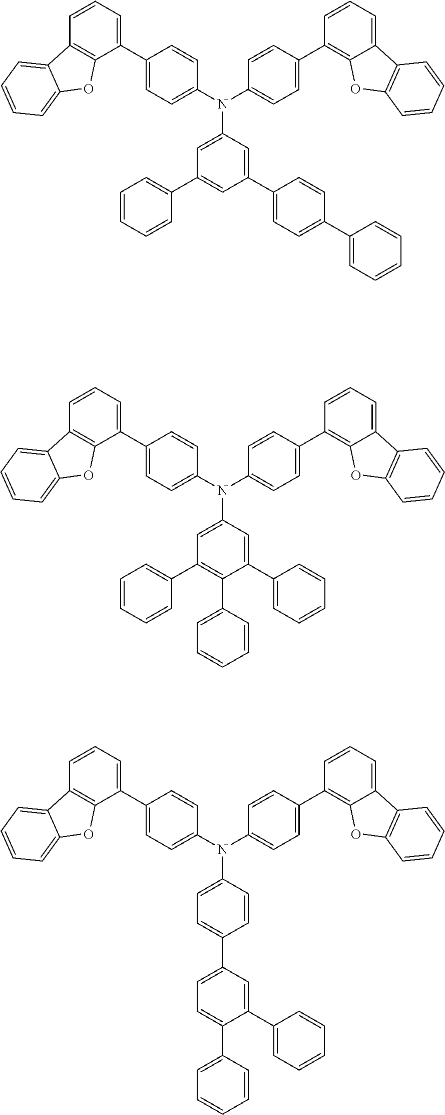 [SMILES: c1ccc(-c2ccc(-c3cc(-c4ccccc4)cc(N(c4ccc(-c5cccc6c5oc5ccccc56)cc4)c4ccc(-c5cccc6c5oc5ccccc56)cc4)c3)cc2)cc1 ; c1ccc(-c2cc(N(c3ccc(-c4cccc5c4oc4ccccc45)cc3)c3ccc(-c4cccc5c4oc4ccccc45)cc3)cc(-c3ccccc3)c2-c2ccccc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2-c2ccccc2)cc1]

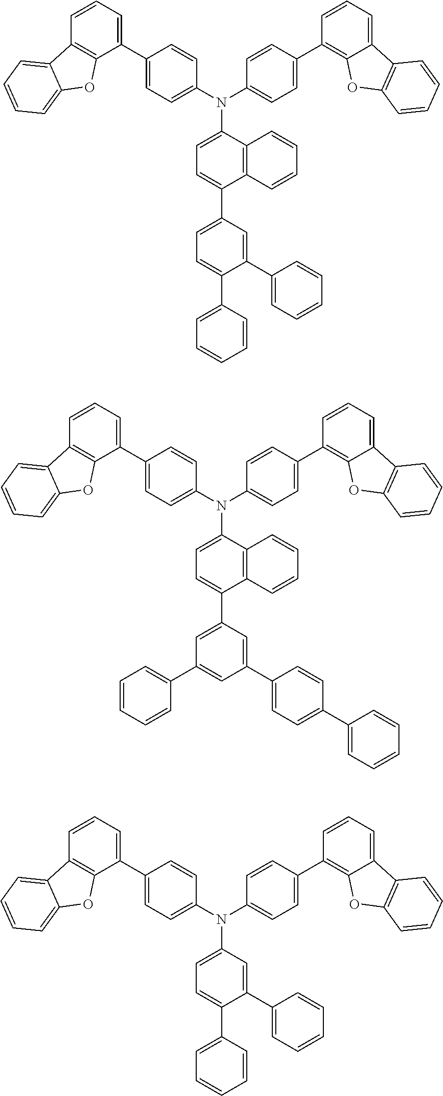 [SMILES: c1ccc(-c2ccc(-c3ccc(N(c4ccc(-c5cccc6c5oc5ccccc56)cc4)c4ccc(-c5cccc6c5oc5ccccc56)cc4)c4ccccc34)cc2-c2ccccc2)cc1 ; c1ccc(-c2ccc(-c3cc(-c4ccccc4)cc(-c4ccc(N(c5ccc(-c6cccc7c6oc6ccccc67)cc5)c5ccc(-c6cccc7c6oc6ccccc67)cc5)c5ccccc45)c3)cc2)cc1 ; c1ccc(-c2ccc(N(c3ccc(-c4cccc5c4oc4ccccc45)cc3)c3ccc(-c4cccc5c4oc4ccccc45)cc3)cc2-c2ccccc2)cc1]

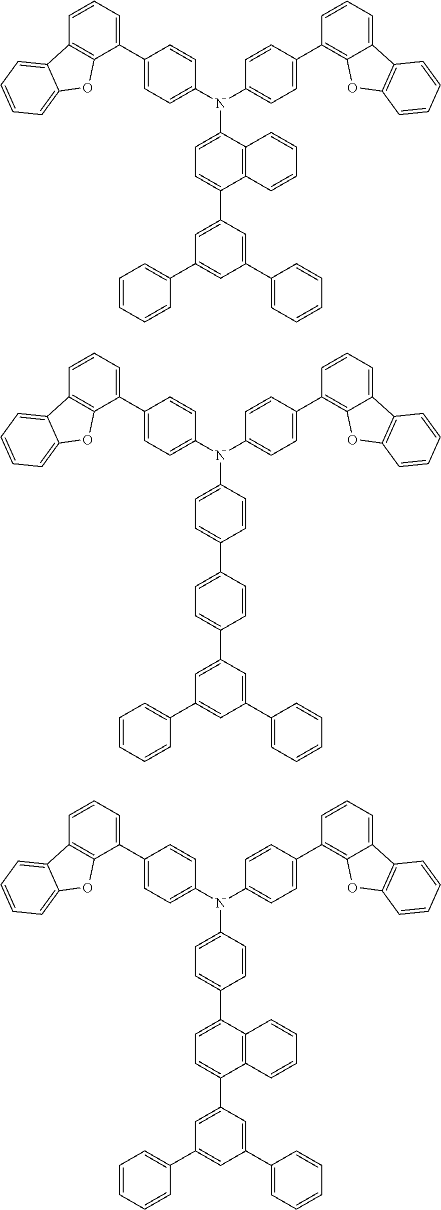 [SMILES: c1ccc(-c2cc(-c3ccccc3)cc(-c3ccc(N(c4ccc(-c5cccc6c5oc5ccccc56)cc4)c4ccc(-c5cccc6c5oc5ccccc56)cc4)c4ccccc34)c2)cc1 ; c1ccc(-c2cc(-c3ccccc3)cc(-c3ccc(-c4ccc(N(c5ccc(-c6cccc7c6oc6ccccc67)cc5)c5ccc(-c6cccc7c6oc6ccccc67)cc5)cc4)cc3)c2)cc1 ; c1ccc(-c2cc(-c3ccccc3)cc(-c3ccc(-c4ccc(N(c5ccc(-c6cccc7c6oc6ccccc67)cc5)c5ccc(-c6cccc7c6oc6ccccc67)cc5)cc4)c4ccccc34)c2)cc1]

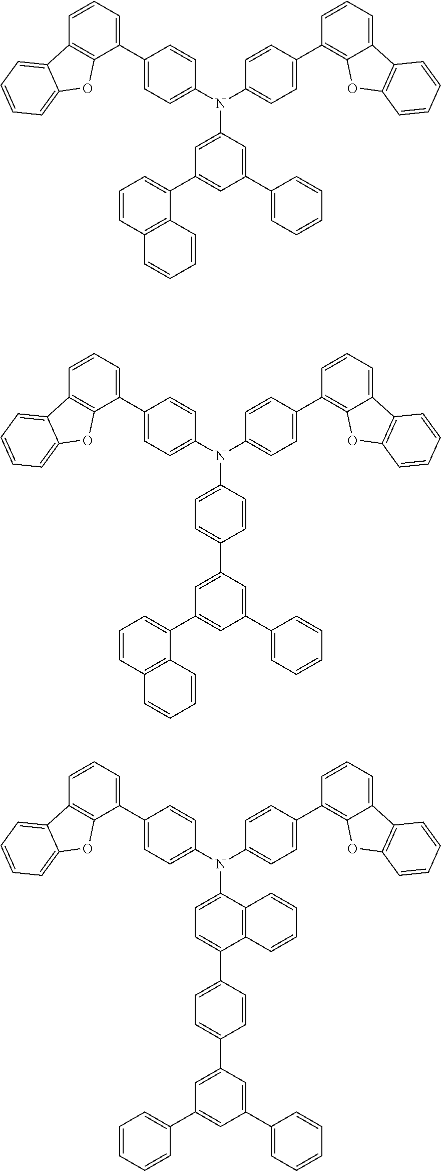 [SMILES: c1ccc(-c2cc(-c3cccc4ccccc34)cc(N(c3ccc(-c4cccc5c4oc4ccccc45)cc3)c3ccc(-c4cccc5c4oc4ccccc45)cc3)c2)cc1 ; c1ccc(-c2cc(-c3ccc(N(c4ccc(-c5cccc6c5oc5ccccc56)cc4)c4ccc(-c5cccc6c5oc5ccccc56)cc4)cc3)cc(-c3cccc4ccccc34)c2)cc1 ; c1ccc(-c2cc(-c3ccccc3)cc(-c3ccc(-c4ccc(N(c5ccc(-c6cccc7c6oc6ccccc67)cc5)c5ccc(-c6cccc7c6oc6ccccc67)cc5)c5ccccc45)cc3)c2)cc1]

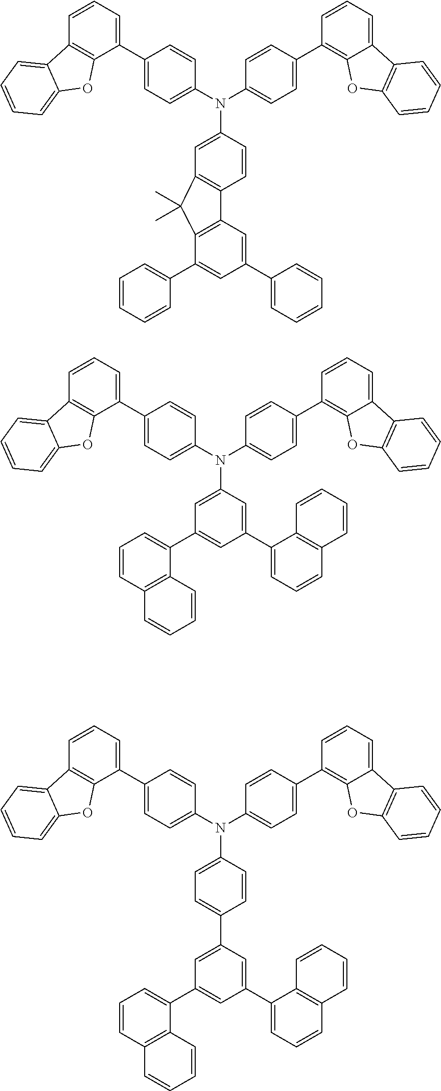 [SMILES: CC1(C)c2cc(N(c3ccc(-c4cccc5c4oc4ccccc45)cc3)c3ccc(-c4cccc5c4oc4ccccc45)cc3)ccc2-c2cc(-c3ccccc3)cc(-c3ccccc3)c21 ; c1ccc2c(-c3cc(-c4cccc5ccccc45)cc(N(c4ccc(-c5cccc6c5oc5ccccc56)cc4)c4ccc(-c5cccc6c5oc5ccccc56)cc4)c3)cccc2c1 ; c1ccc2c(-c3cc(-c4ccc(N(c5ccc(-c6cccc7c6oc6ccccc67)cc5)c5ccc(-c6cccc7c6oc6ccccc67)cc5)cc4)cc(-c4cccc5ccccc45)c3)cccc2c1]

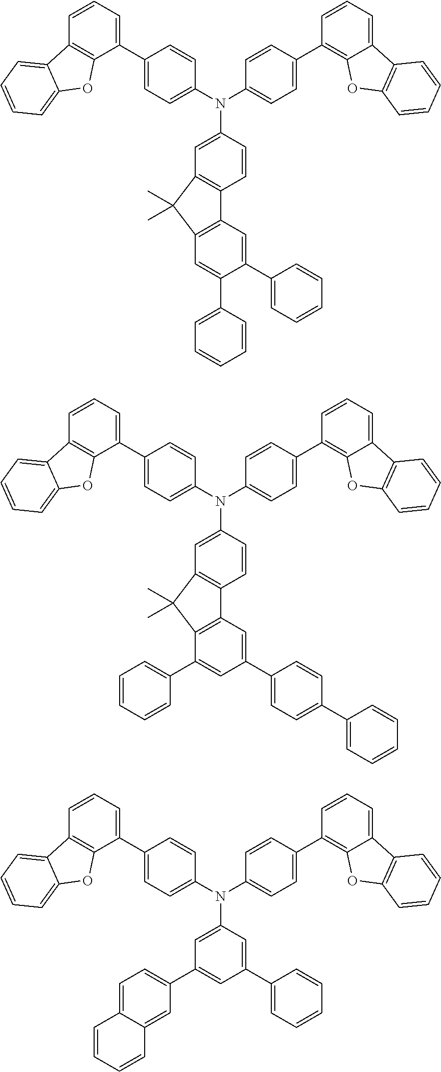

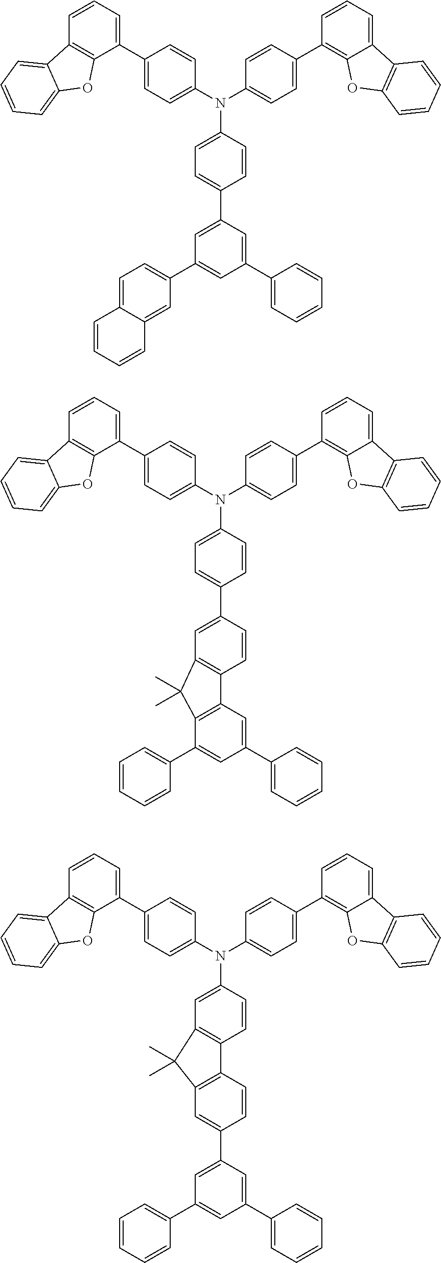

Preferably, a thickness of the second hole transport layer 1322 may be 20-50 nm, more preferably 35-45 nm.

The organic light-emitting layer 133 may include a light emitting host material. The light emitting host material may be a thermal activation delay fluorescent material.

In the present disclosure, the organic light-emitting display may be preferably a green light device, that is, the light emitting host material is a green light thermal activation delay fluorescent material.

Preferably, the light emitting host material may be selected from a compound represented by structural formula (2) below:

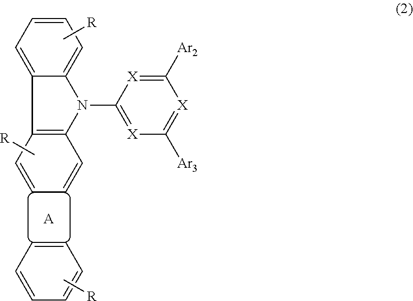

where a ring A is represented by a structural formula (2-1) below:

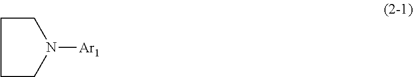

The ring A and a ring adjacent to the ring A may form a condensed ring. X may be selected from N or CH, wherein at least one X is selected from N. Ar₁, Ar₂, and Ar₃ may be each independently selected from substituted or unsubstituted non-condensed ring aryl hydrocarbon substituent, and substituted or unsubstituted non-condensed ring aryl heterocyclic substituent, and it is not ruled out that Ar₂ and Ar₃ may form a condensed ring structure through an aromatic ring containing heteroatom. R may be selected from H atom and monovalent substituent.

More preferably, the light emitting host material may be selected from compounds represented by the following structural structural formulas:

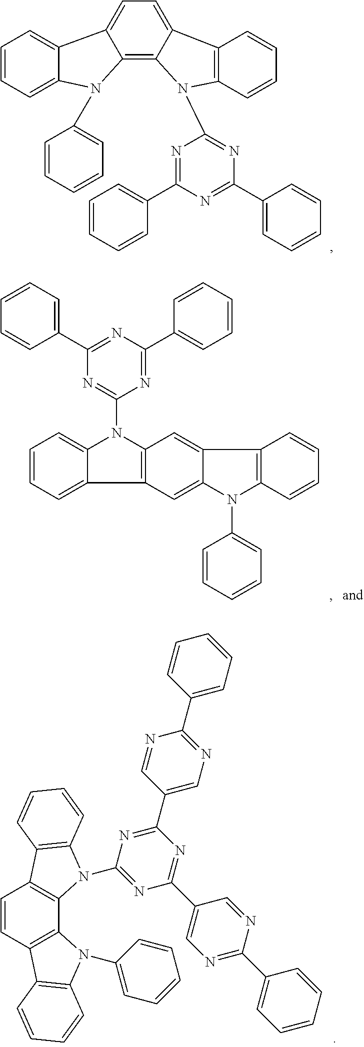

Certainly, the light emitting host material is not limited to the above-mentioned compounds represented by the above-mentioned structural formulas, but can be compounds represented by the following structural formulas:

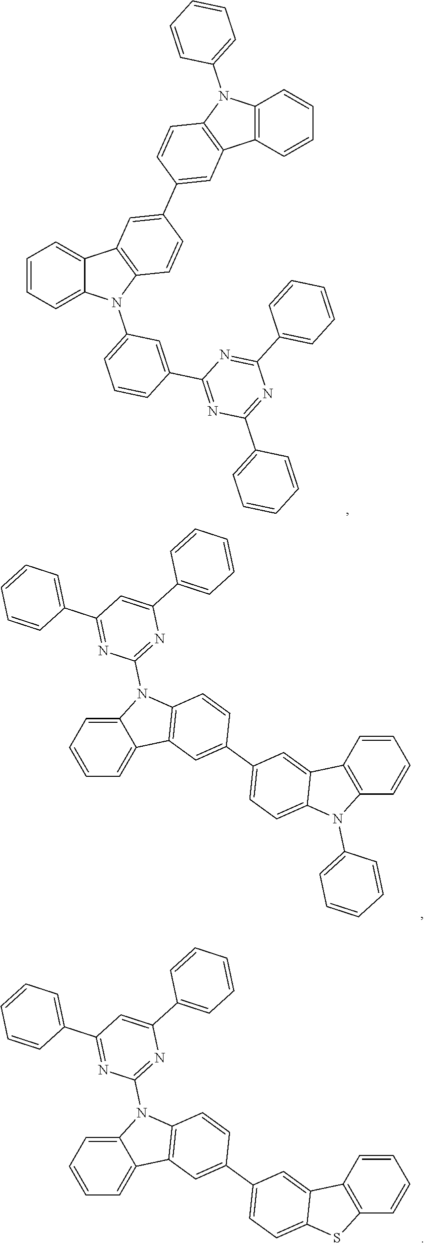

In practical use, the organic light-emitting layer 133 may generally further include a coloring matter. The coloring matter may be selected from coloring matters known to those skilled in the art.

Preferably, a thickness of the organic light-emitting layer may be 10-40 nm.

Certainly, the organic light-emitting display is not limited to the green light device, but can be a red light device or a blue light device.

The organic light-emitting display adopts two hole transport layers, wherein the second hole transport layer acts as both an electron blocking layer and an optical compensation layer, and is cooperated with the thermal activation delay fluorescent material of the organic light-emitting layer, thereby improving the current efficiency and service life of the organic light-emitting display. Furthermore, the process difficult is not increased compared with the prior art.

A display device is further provided in the present disclosure. The display device may include the organic light-emitting display described in the present disclosure.

The present disclosure will be further described with reference to the following exemplary embodiments.

### Example One

As shown in FIG. 1, a top emitting green light single host device may include a first electrode 110, a hole injection layer 131, a first hole transport layer 1321, a second hole transport layer 1322, an organic light-emitting layer 133, an electron transport layer 134, an electron injection layer 135, a second electrode 120, and a circular polarizer layer 190 which are sequentially arranged from bottom to top.

The first electrode 110 may be an indium tin oxide electrode with a thickness of 40 nm.

The hole injection layer 131 may be made of HAT with a thickness of 10 nm.

The first hole transport layer 1321 may be made of NPB with a thickness of 20 nm.

The second hole transport layer 1322 may be made of a material represented by the following structural formula, with a thickness of 40 nm:

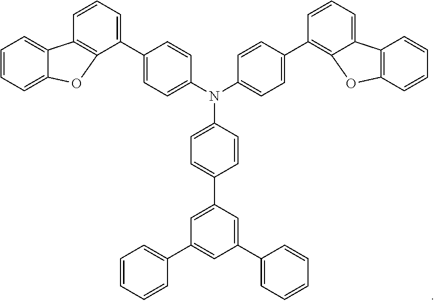 [SMILES: c1ccc(-c2cc(-c3ccccc3)cc(-c3ccc(N(c4ccc(-c5cccc6c5oc5ccccc56)cc4)c4ccc(-c5cccc6c5oc5ccccc56)cc4)cc3)c2)cc1]

The organic light-emitting layer 133 may be made of a material represented by the following structural formula, with a thickness of 30 nm:

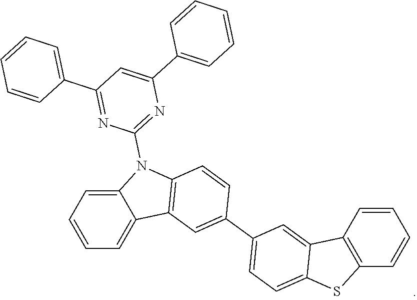 [SMILES: c1ccc(-c2cc(-c3ccccc3)nc(-n3c4ccccc4c4cc(-c5ccc6sc7ccccc7c6c5)ccc43)n2)cc1]

The electron transport layer 134 may be a co-evaporation layer of Bphen and Liq with a thickness of 30 nm.

The electron injection layer 135 may be made of magnesium silver alloy with a thickness of 2 nm.

The second electrode 120 may be a silver electrode with a thickness of 16 nm.

The optical coupling layer 190 may be made of Alq₃ with a thickness of 65 nm.

### Comparative Example 1

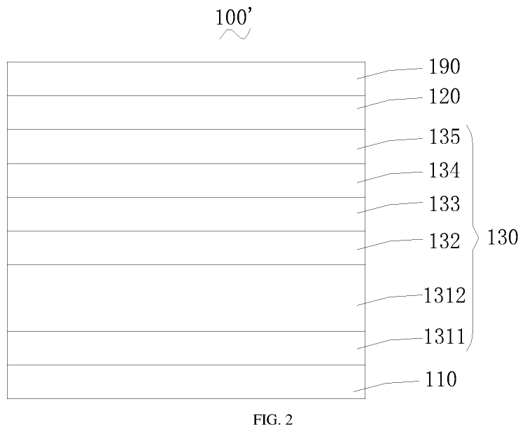

Referring to FIG. 2, Comparative Example 1 is substantially same as Example 1, except that the top emitting green light single host OLED 100′ only include one hole transport layer 132. The hole transport layer 132 is made of the same material as the second hole transport layer 1322 of Example 1.

There are two hole injection layers, i.e., a first hole injection layer 1311 and a second hole injection layer 1312, wherein the second hole injection layer may act as an optical compensation layer with a thickness of 35 nm. The second hole injection layer may be made of 4,4,4-tri(N-3-methyl phenyl-N-phenyl-amino)-triphenylamine (m-MTDATA).

### Comparative Example 2

Comparative Example 2 is substantially same as Comparative Example 1, except that the hole transport layer is made of NPB.

Performance Test

CIE-x Test and CIE-y test:

Chromatic value test is carried out at 1931CIE with a PR705 spectrograph.

Service life test:

Service life decay test is carried out at an initial luminance of 10 Knit with a service life tester, to calculate a time the luminance is decayed to 97% of the initial luminance.

Voltages, current efficiencies, CIE-x, CIE-y, and service lives of the OLED of Example 1 and Comparative Examples 1-2 are respectively tested and listed in Table 1.

TABLE 1

| | | Current | | | |
|---|---|---|---|---|---|
| | Voltage | Efficiency | | | Service life |
| Device | V | (cd/A) | CIE-x | CIE-y | (T97@10Knit) h |
| Example 1 | 4.42 | 97.59 | 0.2377 | 0.7210 | 335 |
| Comparative | 4.68 | 92.53 | 0.2014 | 0.7341 | 170 |
| Example 1 | | | | | |
| Comparative | 4.32 | 87.74 | 0.2168 | 0.7243 | 110 |
| Example 2 | | | | | |

It can be seen from Table 1 that compared with Comparative Examples 1 or 2, the current efficiency, CIE-x, CIE-y, and the service life of the device of Example 1 is greatly increased. Compared with Comparative Example 2, the current efficiency of the device of Example 1 is increased by 11.2%, and the service life of the device of Example 1 is increased by 225 hours which is nearly triple of the service life in Comparative Example 2. Compared with Comparative Example 1, the current efficiency of the device of Example 1 is increased by 10%, and the service life of the OLED of Example 1 is increased by 165 hours which is nearly double of the service life in Comparative Example 1.

Technical features of the above embodiments may be combined arbitrarily. For brief description, not all of the possible combinations of the technical features of the above embodiments are described, but it will be appreciated that these possible combinations belong to the scope of the present disclosure once there is no conflict between the technical features.

The above are embodiments of the disclosure described in detail, and should not be deemed as limitations to the scope of the present disclosure. It should be noted that variations and improvements will become apparent to those skilled in the art to which the present disclosure pertains without departing from its scope. Therefore, the scope of the present disclosure is defined by the appended claims.

1. An organic light-emitting display, comprising:
a first electrode;
a second electrode; and
a functional structure layer, located between the first electrode and the second electrode, wherein the functional structure layer includes a hole injection layer, a first hole transport layer, a second hole transport layer, an organic light-emitting layer, an electron transport layer, and an electron injection layer which are sequentially laminated on the first electrode,
wherein a highest occupied orbital energy level of a first material forming the first hole transport layer is less than a highest occupied orbital energy level of a second material forming the second hole transport layer, a triplet state energy level of the second material is greater than 2.5 eV,
the organic light-emitting layer includes a light emitting host material, and the light emitting host material includes a thermal activation delay fluorescent material.

2. The organic light-emitting display of claim 1, wherein the second material forming the second hole transport layer is selected from a compound represented by a structural formula (1) below: 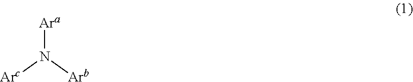
wherein
—Ar^{a} is represented by a structural formula (1-1) or (1-2) below,
-L^{a}Ar^{d})ₙ (1-1)
-L^{a}-CH₃₋ₙAr^{d})ₙ (1-2)
where -L^{a} is selected from aromatic ring containing 6 to 25 ring carbon atoms, or aromatic heterocyclic ring containing 5 to 25 ring atoms, —Ar^{d} is selected from aryl group containing 6 to 25 ring carbon atoms, or heteroaryl group containing 5 to 25 ring atoms, n is selected from 2 or 3, and a plurality of —Ar^{d} are same or different;
—Ar^{b} is represented by a structural formula (1-3) below: 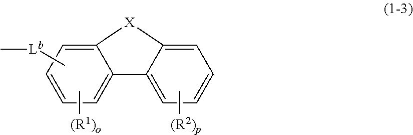
where -L^{b} is selected from arylene group containing 6 to 25 ring carbon atoms, or heteroarylene group containing 5 to 25 ring atoms, L^{b} is connected by a single bond to a ring connecting with R¹,
R¹ and R² are each independently selected from alkyl group containing 1 to 15 carbon atoms, alkenyl group containing 2 to 15 carbon atoms, naphthenic group containing 3 to 15 ring carbon atoms, aryl group containing 6 to 25 ring carbon atoms, heteroaryl group containing 5 to 25 ring atoms, trialkylsilyl group formed by alkyl groups each containing 1 to 15 carbon atoms, a triarylsilyl group formed by aryl groups each containing 6 to 25 ring carbon atoms, alkylarylsilyl group formed by an alkyl group containing 1 to 15 carbon atoms and an aryl group containing 6 to 25 ring carbon atoms, carbazolyl group, halogen atom, or cyano group; o is selected from an integer of 0 to 3; p is selected from an integer of 0 to 4; a plurality of R¹ adjacent to each other are bondable to each other to form a ring, a plurality of R² adjacent to each other are bondable to each other to form a ring, R¹ and R² are bondable to each other to form a ring; X is selected from CR³R⁴, NR⁵, O or S; and R³, R⁴ and R⁵ each is independently selected from an alkyl group containing 1 to 15 carbon atoms, or an aryl group containing 6 to 25 ring carbon atoms; and
Ar^{c} is selected from an aryl group containing 6 to 50 ring carbon atoms or a heteroaryl group containing 5 to 25 ring atoms, or a structure represented by the structural formula (1-1), (1-2), or (1-3).

3. The organic light-emitting display of claim 1, wherein the second hole transport layer has a thickness of 20-50 nm.

4. The organic light-emitting display of claim 1, wherein the second hole transport layer has a thickness of 35-45 nm.

5. The organic light-emitting display of claim 1, wherein the light emitting host material includes a green light thermal activation delay fluorescent material.

6. The organic light-emitting display of claim 5, wherein the light emitting host material is selected from a compound represented by a structural formula (2) below: 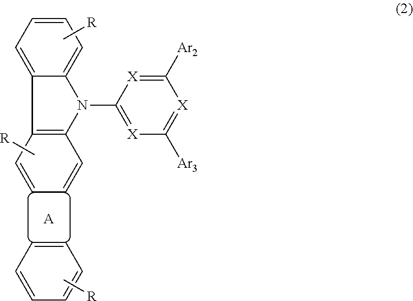
wherein
a ring A is represented by a structural formula (2-1) below 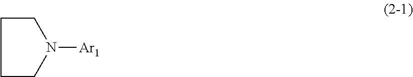
the ring A is fused to a ring adjacent thereto to form a condensed ring; X is selected from N or CH, and at least one X is selected from N; Ar₁, Ar₂, and Ar₃ are each independently selected from non-condensed ring aryl hydrocarbon substituent, or non-condensed ring aryl heterocyclic substituent, and it is not ruled out that Ar₂ and Ar₃ form a condensed ring structure through an aromatic ring containing a heteroatom; and R is selected from H atom or monovalent substituent.

7. The organic light-emitting display of claim 6, wherein the light emitting host material is selected from one of compounds represented by the following structural formulas (3-1), (3-2) and (3-3) respectively:

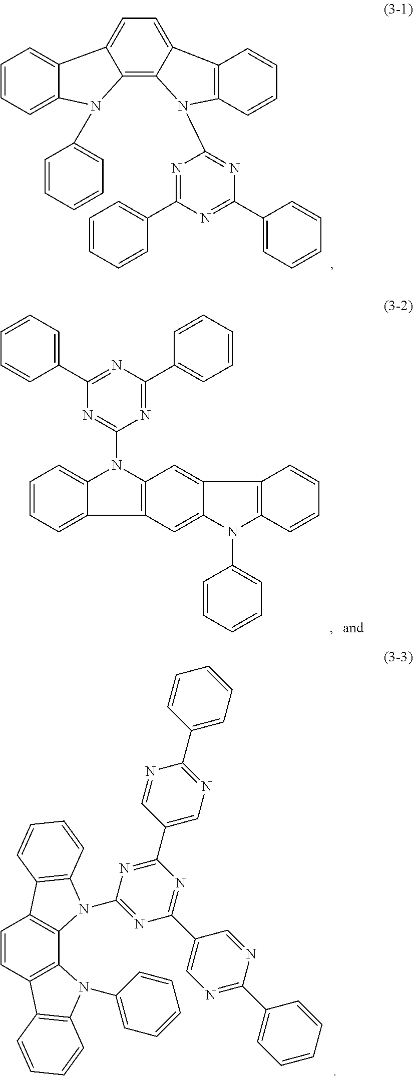

8. The organic light-emitting display of claim 1, wherein the light emitting host material includes a red light thermal activation delay fluorescent material.

9. The organic light-emitting display of claim 1, wherein the first hole transport layer has a thickness of 1-40 nm.

10. The organic light-emitting display of claim 1, wherein a circular polarizer layer is further disposed on one side of the second electrode far away from the functional structure layer.

11. The organic light-emitting display of claim 1, wherein the organic light-emitting layer has a thickness of 10-40 nm.

12. (canceled)

13. The organic light-emitting display of claim 1, wherein the second hole transport layer serves as an electron blocking layer and an optical compensation layer apart from a hole transport layer.

14. The organic light-emitting display of claim 9, wherein first hole transport layer has a thickness of 5-20 nm.

15. The organic light-emitting display of claim 1, wherein the second hole transport layer is made of aryl tertiary amine compound.

16. The organic light-emitting display of claim 1, wherein the light emitting host material includes a thermal activation delay fluorescent material.

17. The organic light-emitting display of claim 1, wherein the organic light-emitting layer includes a coloring matter.

18. The organic light-emitting display of claim 1, wherein the first electrode is an indium tin oxide electrode.

19. The organic light-emitting display of claim 1, wherein the second electrode is a silver electrode.

20. The organic light-emitting display of claim 1, wherein the first hole transport layer is made of NPB.

21. A display device, comprising an organic light-emitting display, the organic light-emitting display comprising:
a first electrode;
a second electrode; and
a functional structure layer, located between the first electrode and the second electrode, wherein the functional structure layer includes a hole injection layer, a first hole transport layer, a second hole transport layer, an organic light-emitting layer, an electron transport layer, and an electron injection layer which are sequentially laminated on the first electrode,
wherein a highest occupied orbital energy level of a first material forming the first hole transport layer is less than a highest occupied orbital energy level of a second material forming the second hole transport layer, a triplet state energy level of the second material is greater than 2.5 eV,
the organic light-emitting layer includes a light emitting host material, and the light emitting host material includes a thermal activation delay fluorescent material.
